(19) United States
(12) Patent Application Publication
(10) Pub. No.: US 2015/0163926 A1
(43) Pub. Date: Jun. 11, 2015

(54) COATING DEVICE AND COATING METHOD

(71) Applicant: MICROCOSM TECHNOLOGY CO., LTD., TAINAN CITY (TW)

(72) Inventor: TANG-CHIEH HUANG, TAINAN CITY (TW)

(73) Assignee: MICROCOSM TECHNOLOGY CO., LTD., TAINAN CITY (TW)

(21) Appl. No.: 14/251,295

(22) Filed: Apr. 11, 2014

(30) Foreign Application Priority Data
Dec. 11, 2013 (TW) 102145568

(51) Int. Cl. H05K 3/46; H05K 3/00

(52) U.S. Cl. CPC H05K 3/4664; H05K 3/0088

(57) ABSTRACT

The disclosure provides a coating device and a coating method. The coating device is used for coating viscous ink on a substrate to form a film. The substrate includes two opposite mounting surfaces. The coating device comprising: an accommodating mechanism, a coating mechanism and a forming mechanism. The coating mechanism includes two coating units. Each coating unit includes a rotatable filling roller for filling with pressure the viscous ink in the hole on the corresponding mounting surface to form an initial layer. The forming mechanism is used for scraping the initial layer covering on the mounting surfaces to form the film. The method of coating and then adjusting the thickness of the film may improve the quality of the products. By using the above disclosure, the production line can be simplified to lower the device costs, and the manufacturing time can be reduced to improve the manufacturing efficiency.

### BACKGROUND OF THE INVENTION

1. Field of the Invention

The present invention relates to a coating device and a coating method, and in particular, to a coating device and a coating method for coating viscous ink on a substrate in a process of manufacturing a Flexible Printed Circuit Board (FPCB).

2. Description of the Related Art

When a Flexible Printed Circuit Board (FPCB) is manufactured, working procedures such as coating photoresist, exposure, developing, etching, coating ink, and baking are generally performed. For the process of coating ink, generally, a coating device is used to coat ink on a substrate to form a film, and the film may provide insulation protection and protect a copper wire, so as to prevent an electronic component from being welded to an incorrect place.

Referring to FIG. 1, a coating device 91 disclosed in a utility model with a Taiwan patent certificate number M418024 includes a base 911, a coating roller unit 912 and a conveying roller 913. The base 911 is used for accommodating ink 99. The coating roller unit 912 is disposed above the base 911. The conveying roller 913 is disposed beside the coating roller unit 912 and may drive a substrate 97 to move along a production line direction 900. The substrate 97 includes two opposite mounting surfaces 971. When the substrate 97 is conveyed to the coating device 91 along the production line direction 900, the coating roller unit 912 may coat the ink 99 on one of the mounting surfaces 971 of the substrate 97, so as to form a film 98.

Referring to FIG. 2, another conventional coating device 81 includes a base 811, a coating roller 812, a conveying roller 813 and a clearance roller 814. The base 811 is used for accommodating ink 89. The coating roller 812 is disposed above the base 811. The conveying roller 813 may drive a substrate 87 to move along a production line direction 800. The clearance roller 814 is disposed beside the coating roller 812. The substrate 87 includes two opposite mounting surfaces 871. In a rotation process, the ink 89 is coated on the surface of the coating roller 812, and the ink 89 on the surface of the coating roller 812 is driven to move towards the substrate 87. In this case, an interval between the clearance roller 814 and the coating roller 812 may be controlled, thus volume of the ink 89 coated on the coating roller 812 may be controlled. Therefore, the coating roller 812 may coat the quantitative ink 89 on one of the mounting surfaces 871 of the substrate 87 to form a film 88 with the uniform thickness and a smooth surface.

However, in practical applications of the foregoing two coating devices, because circuits are generally disposed on the surface of the substrate, the mounting surface is uneven and includes blind holes or through holes. Therefore, when the foregoing two coating devices coat quantitative ink on one of the mounting surfaces of the substrate, a part of the ink is filled into the blind holes or through holes of the substrate, so that the problems of generation of holes and discontinuity on the film covering near the blind holes or through holes may occur. In addition, for the foregoing two coating devices, if the viscosity of the used ink is high so that the ink is low in the fluidity, the ink may not be fully filled in the foregoing blind holes or through holes, leading to that bubbles are generated between the manufactured film and substrate, which thereby lowers quality and aesthetics of products.

More importantly, in a single procedure, the foregoing two coating devices only coat the ink on one of the mounting surfaces of the substrate. If the ink needs to be coated on two opposite mounting surfaces of the substrate, the substrate often needs to be rolled first after one of the mounting surfaces is coated, so that the coating device can be used again to coat the other mounting surface. For the foregoing two procedures, an operation time is long, and manufacturing efficiency is reduced. The foregoing two procedures require more devices and components, which are also complicated, thereby improving device costs.

### SUMMARY OF THE INVENTION

The present disclosure provides a coating device for coating viscous ink on a substrate to form a film. The substrate is conveyed along a plummet direction. The substrate includes two opposite mounting surfaces and a plurality of holes. The mounting surfaces are opposite and uneven, and the holes are separately formed on the mounting surfaces. The coating device includes: an accommodating mechanism, a coating mechanism and a forming mechanism.

The accommodating mechanism is used for accommodating the viscous ink and includes a channel for providing the substrate to pass through. The coating mechanism is disposed above the accommodating mechanism, and is used for coating the viscous ink on the substrate passing through the channel. The coating mechanism includes two coating units. The two coating units are separately disposed on two opposite sides of the substrate. The coating units separately transfer the viscous ink in the accommodating mechanism onto the mounting surfaces. Each coating unit includes a rotatable filling roller for filling with pressure the viscous ink in the hole on the corresponding mounting surface to form an initial layer. The forming mechanism is disposed above the coating mechanism, and is used for scraping the initial layer covering on the mounting surfaces to adjust the thickness of the initial layer to form the film.

The present disclosure further provides a coating method for coating viscous ink on a substrate to form a film. The substrate is conveyed along a plummet direction. The substrate includes two opposite mounting surfaces and a plurality of holes. The mounting surfaces are opposite and uneven, the holes are separately formed on the mounting surfaces. The viscosity of the viscous ink is 1,000 cps to 200,000 cps. The coating method includes: separately coating the viscous ink on the mounting surfaces, and filling with pressure the viscous ink in the hole on the mounting surfaces to form an initial layer; and scraping the initial layer covering on the mounting surface to adjust the thickness of the initial layer to form the film.

According to the invention, the film may be formed on two mounting surfaces of the substrate by using a single procedure. By using the design of the above structure, the production line can be simplified to lower the device costs, and the manufacturing time can be reduced to improve the manufacturing efficiency. Additionally, the filling roller may exert pressure on the viscous ink to fully fill the viscous ink in the hole on the mounting surface so as to form the initial layer. Then, the initial layer covering the mounting surface may be scraped by the forming mechanism to form the film with the predetermined thickness. The method of coating and then adjusting the thickness of the film indeed improve the quality of the products.

### BRIEF DESCRIPTION OF THE DRAWINGS

The invention will be described according to the appended drawings in which:

FIG. 1 is a schematic view of a conventional coating device according to a utility model with a Taiwan patent certificate number M418024.

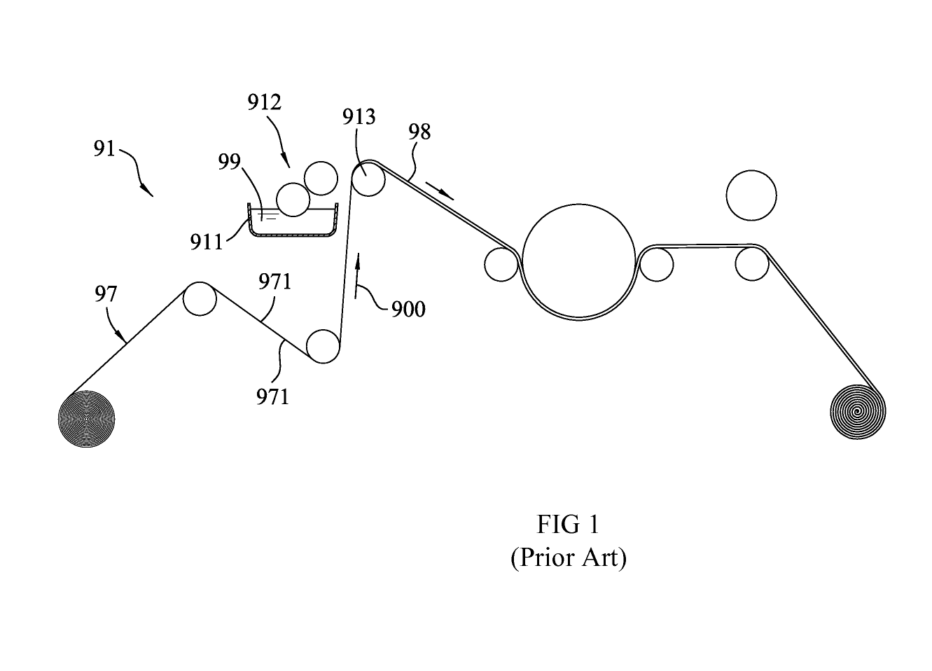

FIG. 2 is a schematic view of another conventional coating device.

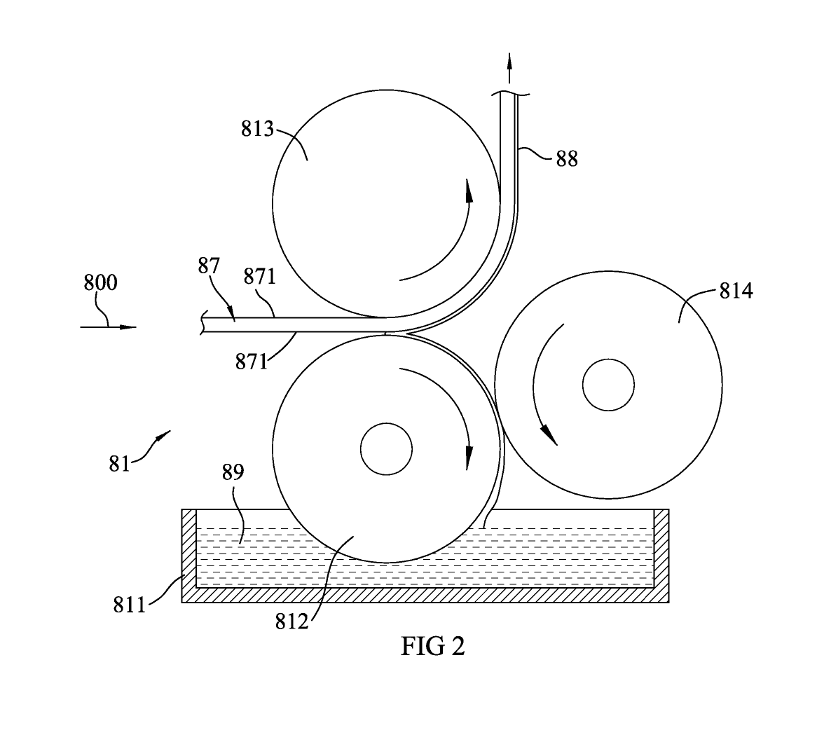

FIG. 3 is a schematic view of a coating device in accordance with a first embodiment.

FIG. 4 is a partial enlarged schematic view of FIG. 3 in accordance with the first embodiment.

FIG. 5 is a perspective view of the coating device omitting the adjusting unit in accordance with the first embodiment.

FIG. 6 is a partial cross-sectional schematic view along A-A line in FIG. 3 in accordance with the first embodiment.

FIG. 7 is a schematic view of a coating device omitting the adjusting unit in accordance with a second embodiment.

FIG. 8 is a schematic view of a coating device in accordance with a third embodiment.

### DETAILED DESCRIPTION OF THE INVENTION

Reference numerals may be repeated throughout the embodiments, but this does not require that features of one embodiment apply to another embodiment, even if they share the same reference numeral.

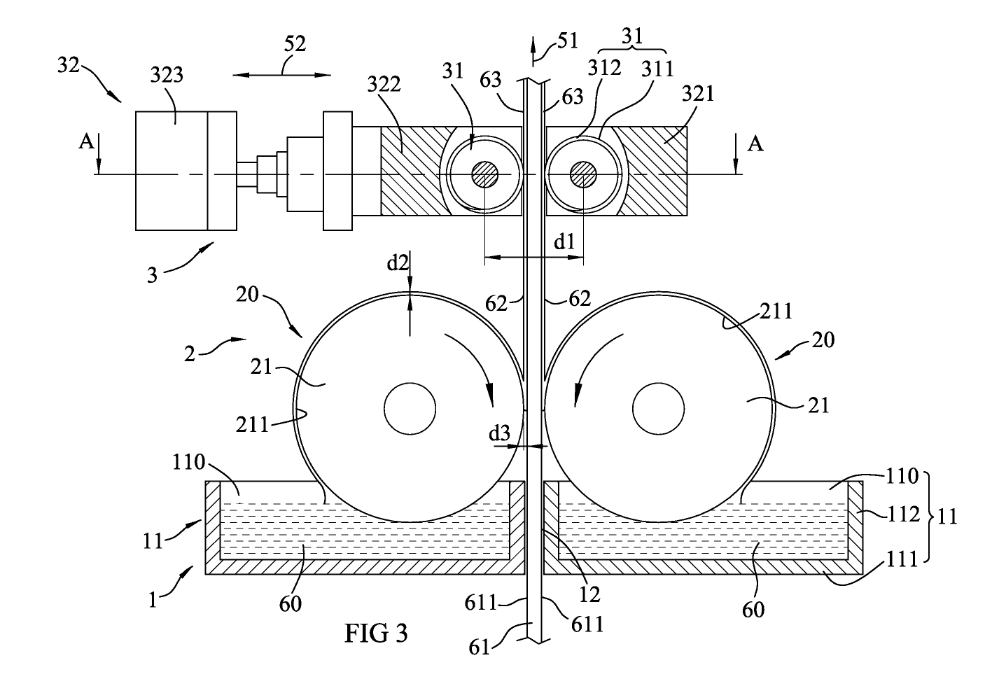

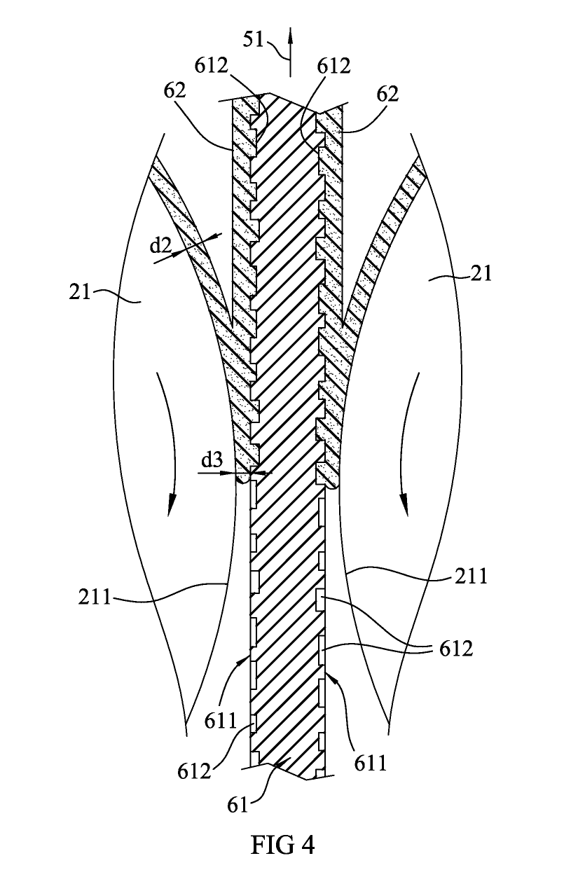

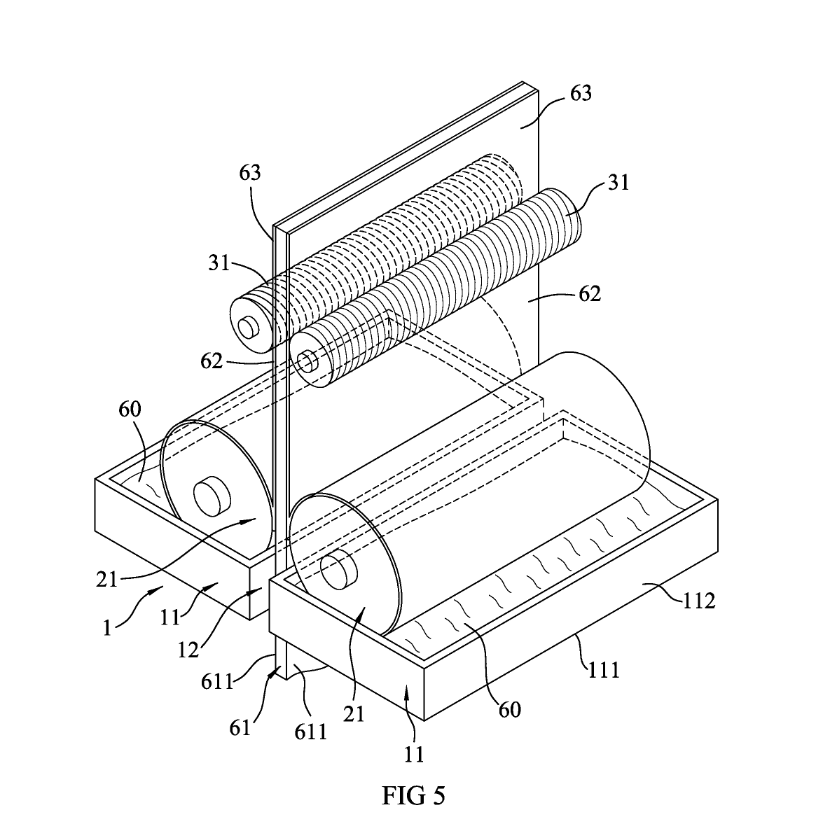

Referring to FIG. 3, FIG. 4, and FIG. 5, they show a coating device applied in a procedure of manufacturing a Flexible Printed Circuit Board (FPCB) according to a first embodiment of the present invention. A substrate 61 is conveyed to the coating device in this embodiment along a plummet direction 51, and the coating device is used for coating viscous ink 60 on the substrate 61 to form a film 63.

In this embodiment, the substrate 61 is continuously conveyed to the coating device from bottom to top along the plummet direction 51 in a roll to roll manner. Additionally, in implementation, the substrate 61 may also be first conveyed to the coating device from top to bottom against the plummet direction 51 by using a sheet by sheet manner, and then move from bottom to top along the plummet direction 51 so as to perform coating operation.

The substrate 61 in this embodiment may be a FPCB with two surfaces having circuits, and includes two opposite mounting surfaces 611 and several holes 612. The mounting surfaces 611 are opposite and uneven because of circuit. The several holes 612 are separately formed on the mounting surfaces 611 and are generated because of circuit. In this embodiment, the holes 612 are blind holes; however, in implementation, the holes 612 may also be through holes which pass through the mounting surfaces 611, or a combination of the blind holes and through holes. Moreover, a size and an arrangement manner of the holes 612 are not limited.

A material of the substrate 61 and form of the hole 612 of the substrate 61 are not limited to the examples of this embodiment. The material of the substrate 61 may also be a macromolecular film, a glass fiber cloth or a metal film, which is not limited. The metal film may be aluminum, copper, and the like. The macromolecular film may be Polyimide (PI), polyethylene terephthalate (PET), and the like. It should be noted that, when a porous material (such as PI) is used as the material of the substrate 61, the hole 612 described in this embodiment is the hole of the porous material. Additionally, in use, when a material (such as PET) with an even surface is used as the material of the substrate 61, roughening processing is generally performed on the surface of the material. In this case, a depression of the surface generated due to the roughening processing is the hole 612 described in this embodiment.

A material of the viscous ink 60 in this embodiment may be photosensitive resin or thermosetting resin, whose viscosity is 1,000 cps to 200,000 cps. Preferably, the viscosity is 1,000 cps to 100,000 cps. The meaning for limiting the numerical values of the viscosity is explained later.

A material of the viscous ink 60 in this embodiment may be Photosensitive polyimide (PSPI). In implementation, material of the viscous ink 60 in this embodiment may be Polyimide (PI), Epoxy, Polymethylmethacrylate (PMMA), Polyurethane (PU), Phenol Formaldehyde Resin (PF), Silicone, Polyvinyl Alcohol (PVA), Polyamide (PA), and the like. However, the material of the viscous ink 60 is not limited to the foregoing examples.

It should be noted that, the viscous ink 60 may be a single material, or a combination of various materials. Powder with a functionality such as silver powder, copper powder, aluminum hydroxide powder or dyeing pigments may be mixed in the above resin. Power is not limited to the foregoing examples.

The coating device includes an accommodating mechanism 1, a coating mechanism 2, and a forming mechanism 3, which are sequentially disposed from bottom to top.

The accommodating mechanism 1 in this embodiment includes two base bodies 11 and a channel 12. The two base bodies 11 are spaced from each other. The channel 12 is disposed between the base bodies 11 and allows the substrate 61 to pass through. Each base body 11 includes a bottom wall 111, an outer wall 112 and an accommodating groove 110. The outer wall 112 extends upwards from a periphery of the bottom wall 111. The accommodating groove 110 is defined by the bottom wall 111 and the outer wall 112 and includes an open upwards. Each accommodating groove 110 can be used for accommodating the viscous ink 60, and a top periphery of each outer wall 112 is higher than a liquid level of the viscous ink 60.

The coating mechanism 2 in this embodiment is disposed above the accommodating mechanism 1, and is used for coating the viscous ink 60 on the substrate 61 passing through the channel 12. The coating mechanism 2 includes two coating units 20. The two coating units 20 are separately disposed on two opposite sides of the substrate 61 and separately disposed above the base body 11. The coating units 20 may separately transfer the viscous ink 60 in the accommodating grooves 110 onto the mounting surfaces 611. Each coating unit 20 includes a filling roller 21. The filling roller 21 is partially disposed in the accommodating groove 110 and partially immersed in the viscous ink 60. In this embodiment, each filling roller 21 has an even outer surface 211; however, in implementation, the outer surface 211 of each filling roller 21 may be changed in design as required, which is not specially limited herein.

It should be noted that, it is feasible only if the accommodating mechanism 1 can be used for accommodating the viscous ink 60, and the means for the accommodating mechanism 1 to accommodate the viscous ink 60 is not limited to the form disclosed in this embodiment.

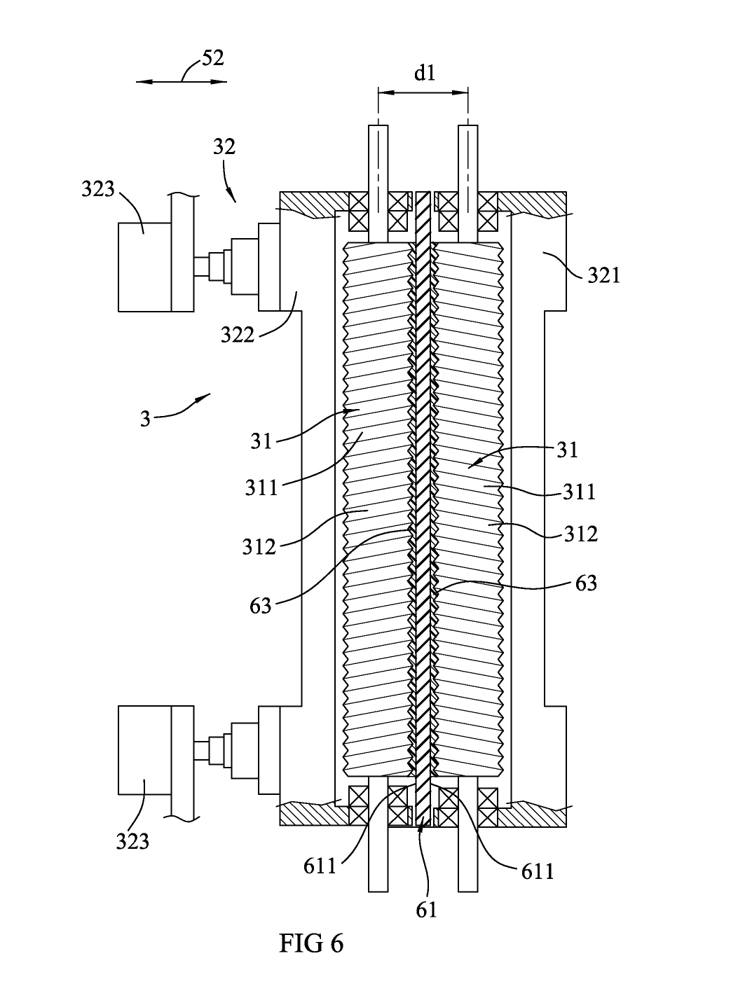

Referring to FIG. 3, FIG. 4, and FIG. 6, the forming mechanism 3 in this embodiment is disposed above the coating mechanism 2, and includes several forming members 31 and an adjusting unit 32. The forming members 31 are correspondingly and separately disposed on opposite sides of the substrate 61 and are separately rotatable. The adjusting unit 32 is used for controlling a distance d1 between axes of the forming members 31. Each forming member 31 includes a scraping surface 311 and a scraping slot 312. The scraping slot 312 is concavely disposed on the scraping surface 311 in a spiral extension manner.

The adjusting unit 32 includes a positioning frame 321, a pushing frame 322 and several pushing members 323. The positioning frame 321 is used for rotatably disposing one forming member 31. The pushing frame 322 can move correspondingly to the positioning frame 321 and can be used for rotatably disposing the other forming member 31. The pushing members 323 can separately push the pushing frame 322 along an adjusting direction 52. The positioning frame 321 and the pushing frame 322 are separately disposed on opposite sides of the forming member 31.

It should be further noted that, the pushing member 323 in this embodiment is in a pneumatic cylinder form, and in implementation, the pushing member 323 may also be in an oil hydraulic cylinder or air and oil hydraulic cylinder form. Additionally, in this embodiment, the filling roller 21 and the forming member 31 are driven to rotate by several driving members which are not shown in the figure. The foregoing driving member is, for example, a servo motor. The technology for driving the foregoing components to rotate is not a key point of the present invention, which is not described herein again.

According to an embodiment of the present invention, the coating method is one of the procedures of manufacturing the FPCB, and includes the following steps:

(1) a coating step: separately coating the viscous ink 60 on the mounting surfaces 611, and filling with pressure the viscous ink 60 in the hole 612 on the mounting surfaces 611 so as to form an initial layer 62.

In this embodiment, when the substrate 61 is conveyed to the coating device along the plummet direction 51, the substrate 61 may first pass through the channel 12 of the accommodating mechanism 1 and reach the position between the coating units 20. Because the filling roller 21 of the coating unit 20 is partially immersed in the viscous ink 60, the viscous ink 60 may attach to the outer surface 211 of the filling roller 21. Moreover, the filling roller 21 may be driven to rotate, so that the viscous ink 60 in the accommodating grooves 110 may be separately taken upwards. The viscous ink 60 is separately coated on the mounting surfaces 611 to form the initial layer 62.

Further, the viscosity of the viscous ink 60 used in this embodiment is 1,000 cps to 200,000 cps, and the viscous ink 60 is low in liquidity. Moreover, the substrate 61 continuously moves along the plummet direction 51 from bottom to top, and the viscous ink 60 attaching on the outer surface 211 of the filling roller 21 may be driven to cover the substrate 61. Simultaneously, the filling rollers 21 may be used for rotatably exerting active force on the viscous ink 60 covering the mounting surface 611. The exerting active force is against the plummet direction 51. Thus, the viscous ink 60 is forced to fully fill in the holes 612 on the mounting surfaces 611. The problem of bubbles generated between the initial layer 62 and the mounting surface 611 of the substrate 61 can be avoided. Therefore, quality and aesthetics of the products can be improved.

It should be noted that, the thickness d2 of the viscous ink 60 attaching on the outer surface 211 of the filling rollers 21 is related to the viscosity of the viscous ink 60. The higher the viscosity of the viscous ink 60 is, the larger the thickness d2 is; and the lower the viscosity of the viscous ink 60 is, the smaller the thickness d2 is. A distance d3 between the outer surface 211 of the filling roller 21 and a protrusion part of the mounting surface 611 must be less than the foregoing thickness d2, so that the viscous ink 60 can be coated on the mounting surface 611. The smaller the distance d3 is, the larger the active force exerted by the filling roller 21 for covering the viscous ink 60 is. In implementation, the thickness d2 and the distance d3 may be adjusted as required, and specific numerical values do not need to be limited.

(2) a forming step: scraping the initial layer 62 covering on the mounting surface 611, so as to adjust the thickness of the initial layer 62 to form the film 63.

In this embodiment, when the substrate 61 continuously moves along the plummet direction 51 upwards to the forming mechanism 3, the active force against the plummet direction 51 may be separately and rotatably exerted on the initial layer 62 by means of the scraping surface 311 of the forming member 31, so as to scrape the initial layer 62 to form the film 63 with the predetermined thickness. The scraped viscous ink 60 may flow out of the mounting surface 611 through the scraping slot 312 of the forming member 31. Then, the substrate 61 may continuously move along the plummet direction 51 to perform subsequent procedures required for manufacturing the FPCB. After the scraping is completed, based on the fluidity of the viscous ink 60 itself, and because the substrate 61 moves along the plummet direction 51, the viscous ink 60 may automatically fill in the depressions generated by scraping. Therefore, the surface of the manufactured film 63 may keep even.

It should be further noted that, the pushing frame 322 may be separately driven by the pushing member 323 to move along the adjusting direction 52, so as to drive the forming member 31 disposed on the pushing frame 322 to move. The foregoing forming member 31 can move towards or move away from the other forming member 31 along the adjusting direction 52, so as to adjust the distance d1 between the axes of the forming members 31. The smaller the distance d1 is, the smaller the thickness of the film 63 is; and the larger the distance d1 is, the larger the thickness of the film 63 is. Therefore, the thickness of the manufactured film 63 can be adjusted.

In addition, in this embodiment, the rotation speed of the forming member 31 for scraping the initial layer 62 may further be separately controlled by the driving member (not shown in the figures), so as to adjust the thickness of the manufactured film 63. That is to say, the faster the rotation speed of the forming member 31 is, the larger the volume of the initial layer 62 scraped by the forming member 31 is, and the smaller the thickness of the manufactured film 63 is. Therefore, the means for the adjusting unit 32 of the forming mechanism 3 to adjust the thickness of the film 63 is not limited to the form disclosed in this embodiment.

It should be specially noted that, the viscosity of the viscous ink 60 is preferred to be 1,000 cps to 200,000 cps. In this case, the viscous ink 60 may be filled in the hole 612 smaller than 1 mm, and the precision of the film thickness according to the coating device in this embodiment may reach within ±3 μm. Preferably, the viscosity of the viscous ink 60 is 1,000 cps to 100,000 cps. In this case, the viscous ink 60 may be filled in the hole 612 smaller than 0.05 mm, and the precision of the film thickness according to the coating device in this embodiment may reach within ±1 μm.

When the viscosity is less than 1,000 cps, the thickness d2 of the viscous ink coated on the outer surface 211 of the filling roller 21 may be too small, leading to that the volume of the viscous ink 60 coated by the filling roller 21 on the mounting surface 611 is too small. Because part of the viscous ink 60 of the initial layer 62 is filled in the hole 612 on the mounting surface 611, the holes and discontinuity of the initial layer 62 are generated, thus a subsequent manufacturing procedure cannot be continued. Additionally, the adhesion of the viscous ink 60 to the mounting surface 611 is also poor, and moreover, the substrate 61 moves along the plummet direction 51. Therefore, the viscous ink 60 may flow downwards, drop, and pass through the channel 12 of the accommodating mechanism 1 due to the gravitation, which causes inconvenience for use.

When the viscosity is greater than 200,000 cps, the fluidity of the viscous ink 60 is extremely poor; the viscous ink 60 is not easily coated on the outer surface 211 of the filling roller 21. Even though the viscous ink 60 is coated on the outer surface 211, it is uneasy to squeeze to fill in the hole 612 smaller than 1 mm. The bubble is generated between the initial layer 62 and the mounting surface 611, which leads to defective products. Additionally, when the scraping surface 311 of the forming member 31 scraps the initial layer 62 to form the film 63, the depressions generated by scraping can not be filled by the fluidity of the viscous ink 60. Surface smoothness of the manufactured film 63 is poor.

According to the above descriptions, in the present invention, the film 63 may be formed on two mounting surfaces 611 of the substrate 61 by using a single procedure. By using the design of the above structure, the production line can be simplified to lower the device costs, and the manufacturing time can be reduced to improve the manufacturing efficiency. It is worth noting that, when only one base body 11 of the accommodating mechanism 1 accommodates the viscous ink 60, the coating device may coat on one mounting surface 611 of the substrate 61 to form the film 63. In other words, in this embodiment, the films 63 may be simultaneously formed on the opposite sides of the substrate 61 as required, or the film 63 is only formed on one side of the substrate 61. The design of selecting to coat two sides or coat one side is rather convenient for use. In use, the material of the viscous ink 60 accommodated in the base body 11 may be the same or different, which does not need to be limited herein.

Further, in this embodiment, the filling roller 21 may separately and rotatably exert pressure on the viscous ink 60 to fully fill the viscous ink 60 in the hole 612 on the mounting surface 611 so as to form the initial layer 62, which may avoid bubble generated between the initial layer 62 and the mounting surface 611. Then, the initial layer 62 covering the mounting surface 611 may be scraped by the forming mechanism 3, so as to form the film 63 with the predetermined thickness. The method of coating and then adjusting the thickness of the film indeed improve the quality of the products. In addition, the thickness of the film 63 may be accurately controlled by controlling the interval d1 of the forming members 31, which thereby may improve the manufacturing precision and yield, and may lower production costs.

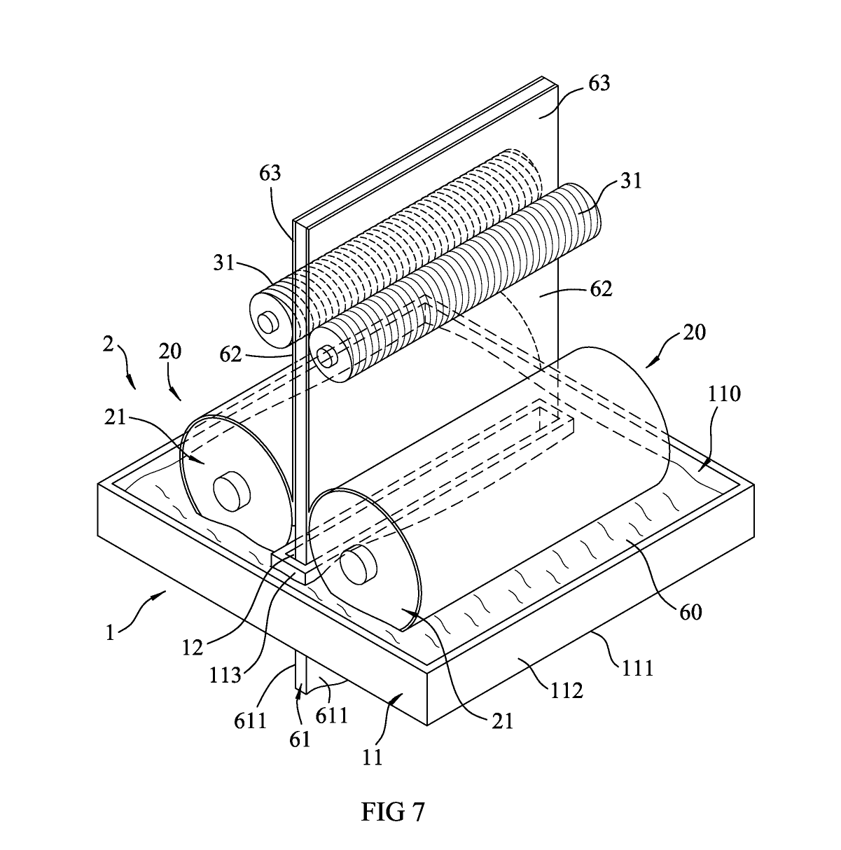

Referring to FIG. 7, a second embodiment of the coating device of the present invention is substantially the same as the first embodiment, and a difference between the two embodiments lies in: a structure of the accommodating mechanism 1.

The accommodating mechanism 1 in this embodiment includes a base body 11 and a channel 12. The base body 11 is disposed below the coating unit 20. The channel 12 is defined and surrounded of the base body 11. The base body 11 includes an inner wall 113, an outer wall 112, a bottom wall 111 and an accommodating groove 110. The inner wall 113 surrounding and defining the channel 12. The outer wall 112 is spaced out from the inner wall 113. The bottom wall 111 connects to a lower part of the inner wall 113 and the outer wall 112. The accommodating groove 110 is defined by the outer wall 112, the inner wall 113 and the bottom wall 111. The accommodating groove 110 may be used for accommodating the viscous ink 60, and top peripheries of the outer wall 112 and the inner wall 113 are higher than a liquid level of the viscous ink 60.

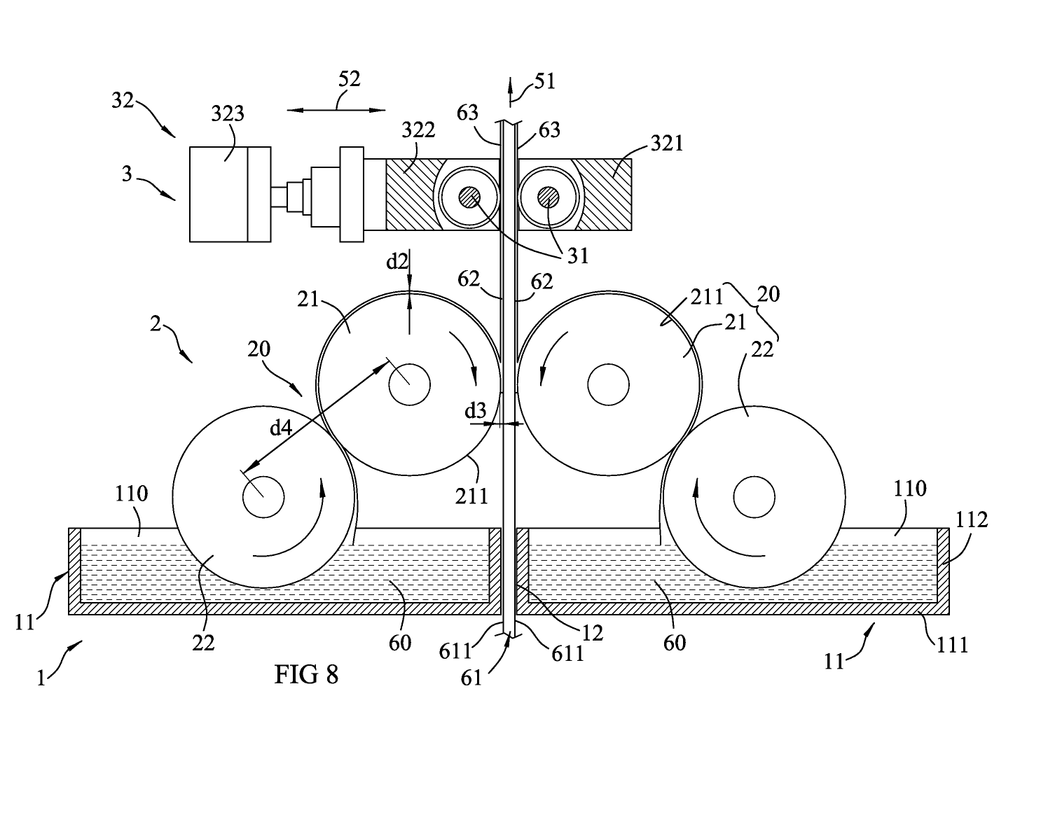

Referring to FIG. 8, a third embodiment of the coating device of the present invention is substantially the same as the first embodiment, and a difference between the two embodiments lies in: a structure of the coating unit 20 of the coating mechanism 2.

Each coating unit 20 includes a filling roller 21 and a feeding roller 22. Each feeding roller 22 is partially disposed in the accommodating groove 110 and is partially immersed in the viscous ink 60. Each filling roller 21 is disposed above the feeding roller 22 which is corresponding to the filling roller 21.

It should be noted that, in use, the feeding roller 22 may coat the viscous ink 60 on a surface of the feeding roller 22 in a rotation process, so that the viscous ink 60 is driven upwards and conveyed from the accommodating groove 110 to the filling roller 21. In this case, a distance d4 between the axes of the feeding roller 22 and the filling roller 21 of each coating unit 20 may be controlled, so that the thickness d2 of the viscous ink 60 coated on the filling roller 21 is controlled. The filling roller 21 can exert pressure on the quantitative viscous ink 60 to fill the viscous ink on the mounting surface 611 of the substrate 61, so as to form the initial layer 62, which thereby further improves the manufacturing precision of this embodiment.

By the support of the feeding roller 22 and limiting the position of the feeding roller 22, counterforce generated during the filling roller 21 exerts pressure on the viscous ink 60 can be balanced, so as to prevent the filling roller 21 from bending and deforming after being used for a long time so as to affect the coating precision, and to improve a service life of the coating device.

In implementation, a structure of the accommodating mechanism 1 in this embodiment may also use a form in the second embodiment, which is not limited to the examples in this embodiment.

While several embodiments of the present disclosure have been illustrated and described, various modifications and improvements can be made by those skilled in the art. The embodiments of the present disclosure are therefore described in an illustrative but not in a restrictive sense. It is intended that the present disclosure should not be limited to the particular forms as illustrated and that all modifications which maintain the spirit and scope of the present disclosure are within the scope defined in the appended claims.

What is claimed is:

1. A coating device for coating viscous ink on a substrate to form a film, the substrate conveyed along a plummet direction, the substrate comprising two opposite mounting surfaces and a plurality of holes, the mounting surfaces being opposite and uneven, the holes separately formed on the mounting surfaces, the coating device comprising:
an accommodating mechanism, for accommodating the viscous ink and comprising a channel for providing the substrate to pass through;
a coating mechanism, disposed above the accommodating mechanism, and for coating the viscous ink on the substrate passing through the channel, the coating mechanism comprising two coating units, the two coating units separately disposed on two opposite sides of the substrate, wherein the coating units separately transfer the viscous ink in the accommodating mechanism onto the mounting surfaces, each coating unit comprises a rotatable filling roller for filling with pressure the viscous ink in the hole on the corresponding mounting surface to form an initial layer; and
a forming mechanism, disposed above the coating mechanism, and for scraping the initial layer covering on the mounting surfaces to adjust the thickness of the initial layer to form the film.

2. The coating device according to claim 1, wherein the accommodating mechanism further comprises two base bodies, the two base bodies are spaced from each other and disposed below the coating mechanism, the channel is disposed between the base bodies, each base body comprises an accommodating groove having an open upwards, the accommodating groove is used for accommodating the viscous ink.

3. The coating device according to claim 2, wherein the filling rollers are partially disposed in the accommodating grooves and partially immersed in the viscous ink, the filling rollers separately coat the viscous ink on the mounting surfaces to form the initial layer.

4. The coating device according to claim 2, wherein each coating unit further comprises a feeding roller, each feeding roller is partially disposed in the accommodating groove and is partially immersed in the viscous ink, the feeding rollers separately convey the viscous ink from the accommodating groove to the filling rollers, the filling rollers separately coat the viscous ink on the mounting surfaces to form the initial layer.

5. The coating device according to claim 1, wherein the accommodating mechanism further comprises a base body, the base body is disposed below the coating unit, the base body comprises an inner wall, an outer wall and an accommodating groove, the inner wall surrounds and defines the channel, the outer wall is spaced out from the inner wall, the accommodating groove is disposed between the outer wall and the inner wall, the accommodating groove is used for accommodating the viscous ink.

6. The coating device according to claim 5, wherein the filling rollers are partially disposed in the accommodating groove and partially immersed in the viscous ink, the filling rollers separately coat the viscous ink on the mounting surfaces to form the initial layer.

7. The coating device according to claim 5, wherein each coating unit further comprises a feeding roller, each feeding roller is partially disposed in the accommodating groove and is partially immersed in the viscous ink, the feeding rollers separately convey the viscous ink from the accommodating groove to the filling rollers, the filling rollers separately coat the viscous ink on the mounting surfaces to form the initial layer.

8. The coating device according to claim 1, wherein the forming mechanism comprises a plurality of forming members, the forming members are correspondingly and separately disposed on opposite sides of the substrate and are separately rotatable, each forming member comprises a scraping surface and a scraping slot, the scraping surface is used for scraping the initial layer covering on the mounting surfaces to form the film, the scraping slot is concavely disposed on the scraping surface in a spiral extension manner.

9. The coating device according to claim 8, wherein the forming mechanism further comprises an adjusting unit, the adjusting unit is used for controlling a distance between the forming members to adjust the thickness of the film, the adjusting unit comprises a positioning frame, a pushing frame and a plurality of pushing members, the positioning frame is used for rotatably disposing one forming member, the pushing frame can move correspondingly to the positioning frame and can be used for rotatably disposing the other forming member, the pushing members can separately push the pushing frame along an adjusting direction, the positioning frame and the pushing frame are separately disposed on opposite sides of the forming member.

10. A coating method for coating viscous ink on a substrate to form a film, the substrate conveyed along a plummet direction, the substrate comprising two opposite mounting surfaces and a plurality of holes, the mounting surfaces being opposite and uneven, the holes separately formed on the mounting surfaces, the viscosity of the viscous ink being 1,000 cps to 200,000 cps, the coating method comprising:
separately coating the viscous ink on the mounting surfaces, and filling with pressure the viscous ink in the hole on the mounting surfaces to form an initial layer; and
scraping the initial layer covering on the mounting surface to adjust the thickness of the initial layer to form the film.
